(19) United States
(12) Patent Application Publication
(10) Pub. No.: US 2007/0241940 A1
(43) Pub. Date: Oct. 18, 2007

(54) AIR PERMEABLE KEYBOARD MODULE AND PORTABLE ELECTRONIC APPARATUS

(75) Inventors: Fong-Chi Hsu, Taipei Hsien (TW); Feng-Ting Hsu, Taipei County (TW)

Correspondence Address: J C PATENTS, INC., 4 VENTURE, SUITE 250, IRVINE, CA, 92618, US

(73) Assignee: JENSIN INTL TECHNOLOGY CORP., Taipei County (TW)

(21) Appl. No.: 11/734,965

(22) Filed: Apr. 13, 2007

(30) Foreign Application Priority Data
Apr. 14, 2006 (TW) 95113332

(51) Int. Cl. H03M 11/00

(52) U.S. Cl. 341/22

(57) ABSTRACT

An air permeable keyboard module suitable for a portable electronic apparatus is provided. The air permeable keyboard module comprises a bottom plate, a flexible printed circuit board (PCB), a plurality of keys, and a unidirectional air permeable material layer. The flexible PCB is disposed on the upper surface of the bottom plate and has a plurality of touch portions. The unidirectional air permeable material layer is disposed on the bottom surface of the bottom plate. The keys are assembled with the bottom plate, and are disposed respectively above the corresponding touch portions.

### CROSS-REFERENCE TO RELATED APPLICATION

This application claims the priority benefit of Taiwan application serial no. 95113332, filed Apr. 14, 2006. All disclosure of the Taiwan application is incorporated herein by reference.

### BACKGROUND OF THE INVENTION

1. Field of the Invention

The present invention relates to an electronic apparatus and a keyboard module thereof. More particularly, the present invention relates to a portable electronic apparatus with a better heat dissipation, and a keyboard module thereof.

2. Description of Related Art

With the advance of science and technology, the use of notebook computers has become popular. The notebook computer is an essential piece of equipment at work and home. When operating a notebook computer, a user usually strokes the keys on a keyboard to input data. Since electronic devices such as hard disks, CPUs and electronic cards inside a notebook computer are disposed beneath the keyboard, if the user carelessly knocks over a container nearby and spills water onto the keyboard, the water easily goes through the keyboard and gets into the notebook computer, thus causing damage to the electronic devices of the notebook computer. Therefore, a waterproof layer is usually disposed on the bottom surface of the keyboard to prevent water from getting into the notebook computer.

In view of the above, the material of the waterproof layer is usually polyethylene terephthalate (PET), a kind of plastic material. Although PET is a good water blocking material, PET does not have air permeable, thus heat cannot penetrate the waterproof layer. The electronic devices of the notebook computer generate waste heat during operation, and the waste heat cannot be effectively dissipated to the outside due to being blocked by the waterproof layer. When the waste heat is continuously accumulated in the notebook computer, the temperature inside the notebook computer may be significantly high to cause damage and or failure of the electronic devices.

### SUMMARY OF THE INVENTION

Accordingly, an objective of the present invention is to provide an air permeable keyboard module with a good air permeable, such that air can easily penetrate the permeable keyboard module.

Another objective of the present invention is to provide a portable electronic apparatus with a better heat dissipation effect.

In order to achieve the above or other objectives, the present invention provides an air permeable keyboard module suitable for a portable electronic apparatus. The air permeable keyboard module comprises a bottom plate, a flexible PCB, a plurality of keys, and a unidirectional air permeable material layer. The flexible PCB is disposed on the upper surface of the bottom plate and has a plurality of touch portions. The keys are assembled with the bottom plate, and disposed respectively above the corresponding touch portions. Moreover, the unidirectional air permeable material layer is disposed on the bottom surface of the bottom plate.

In an embodiment of the present invention, the material of the aforementioned unidirectional air permeable material layer comprises Gore-tex fiber.

In an embodiment of the present invention, the aforementioned unidirectional air permeable material layer comprises a micro-pore structure.

In an embodiment of the present invention, the aforementioned flexible PCB is a thin film switch, a piezoelectric switch, or a capacitance sensing switch.

In an embodiment of the present invention, the aforementioned portable electronic apparatus is a notebook computer.

In order to achieve the above or other objectives, the present invention further provides an air permeable keyboard module suitable for a portable electronic apparatus. The air permeable keyboard module comprises a bottom plate, a thin film switch, a plurality of keys, and a hydrophobic fiber layer. The thin film switch is disposed on the upper surface of the bottom plate and has a plurality of touch portions. The keys are assembled with the bottom plate and disposed respectively above the corresponding touch portions. The hydrophobic fiber layer is disposed on the bottom surface of the bottom plate. Moreover, each of the keys comprises a key cap, a support structure, and an elastic protrusion, wherein the support structure is used to fix the key cap on the bottom plate, and the elastic protrusion is disposed at the bottom of the key cap and corresponds to a touch portion of the thin film switch.

In an embodiment of the present invention, the aforementioned hydrophobic fiber layer comprises a micro-pore structure.

In an embodiment of the present invention, the aforementioned portable electronic apparatus is a notebook computer.

In an embodiment of the present invention, the aforementioned support structure comprises a first bracket and a second bracket cross-pivoted.

In order to achieve the above or other objectives, the present invention further provides a portable electronic apparatus, which comprises a host, a keyboard, and a unidirectional air permeable material layer. The host has a control unit, and the keyboard is assembled on the host control unit and is electrically connected to the control unit. Moreover, the unidirectional air permeable material layer is disposed between the keyboard and the control unit.

In an embodiment of the present invention, the material of the aforementioned unidirectional air permeable material layer comprises Gore-tex fiber.

In an embodiment of the present invention, the aforementioned unidirectional air permeable material layer comprises a micro-pore structure.

In view of the above, in the air permeable keyboard module and the portable electronic apparatus of the present invention, the unidirectional air permeable material layer has waterproof and air permeable properties, such that the waste heat generated by the portable electronic apparatus can be dissipated to the outside via the air permeable keyboard module and the unidirectional air permeable material layer can prevent water from getting into the portable electronic apparatus from the outside. As such, the portable electronic apparatus has a better water proof effect and a better heat dissipation effect.

In order to the make the aforementioned and other objects, features and advantages of the present invention comprehensible, preferred embodiments accompanied with figures are described in detail below.

### BRIEF DESCRIPTION OF THE DRAWINGS

FIG. 1A is a schematic view of an air permeable keyboard module according to an embodiment of the present invention.

FIG. 1B is a partial schematic view of the air permeable keyboard module of FIG. 1A after being disassembled.

FIG. 2 is an exploded view of a portable electronic apparatus according to an embodiment of the present invention.

### DESCRIPTION OF EMBODIMENTS

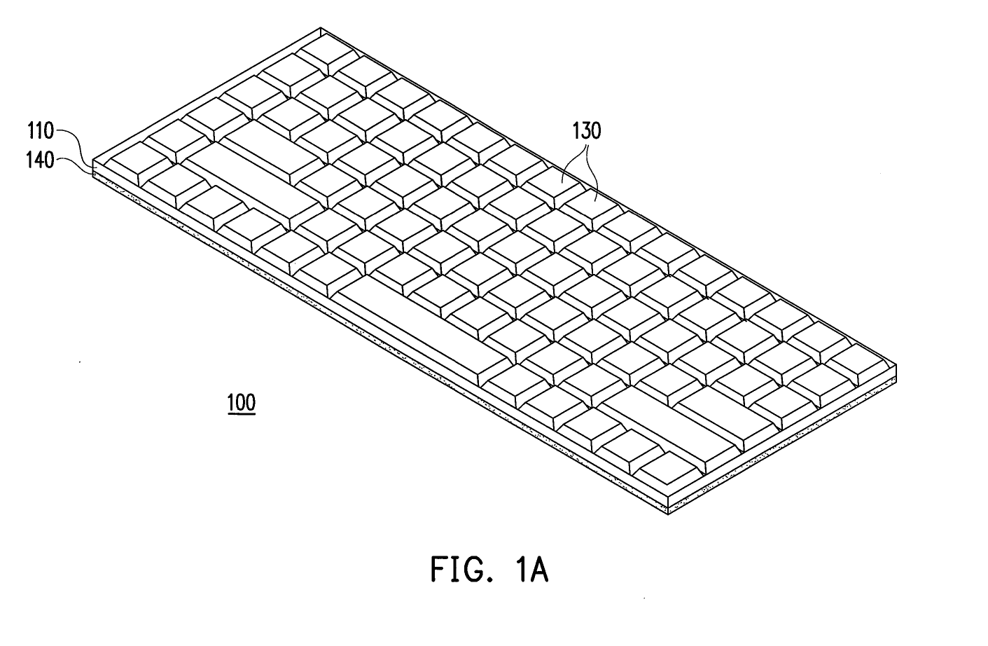

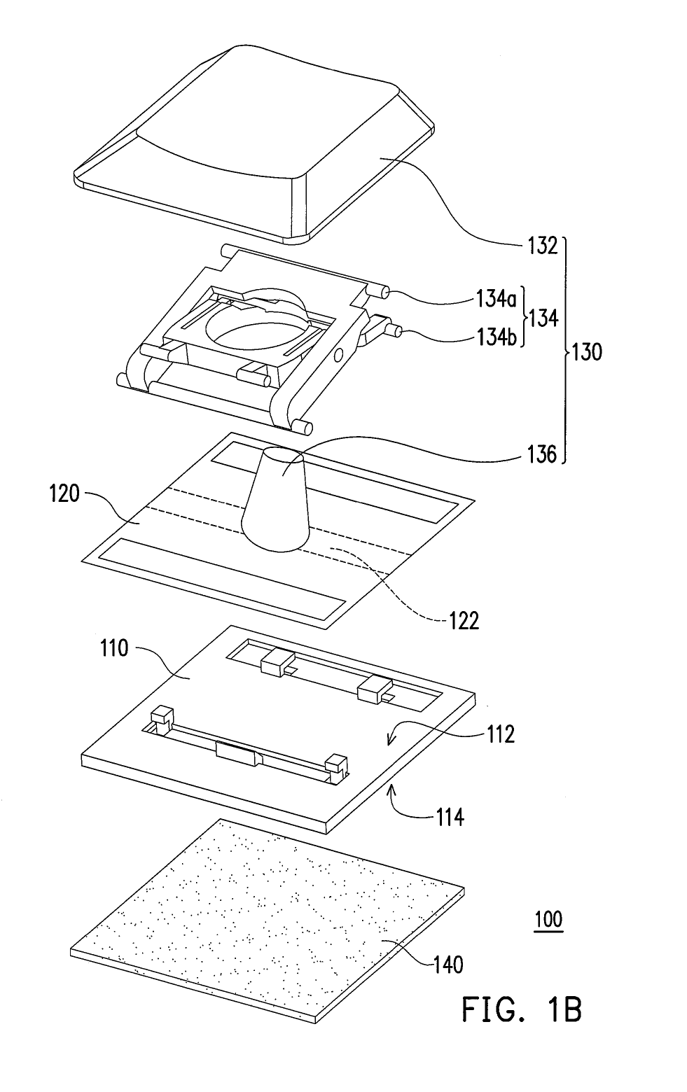

FIG. 1A is a schematic view of an air permeable keyboard module according to an embodiment of the present invention. FIG. 1B is a partial schematic view of the air permeable keyboard module of FIG. 1A after being disassembled. Referring to FIGS. 1A and 1B, an air permeable keyboard module 100 of the present invention is suitable for a portable electronic apparatus (not shown). The air permeable keyboard module 100 comprises a bottom plate 110, a flexible PCB 120, a plurality of keys 130, and a unidirectional air permeable material layer 140. The bottom plate 110 has an upper surface 112 and a bottom surface 114, wherein the flexible PCB 120 is disposed on the upper surface 112 of the bottom plate 110 and the unidirectional air permeable material layer 140 is disposed on the bottom surface 114 of the bottom plate 110. The flexible PCB 120 has a plurality of touch portions 122. The keys 130 are assembled with the bottom plate 110 and disposed respectively above the corresponding touch portions 122. When the user presses the keys 130, the circuit of the touch portions 122 of the flexible PCB 120 is conducted through contact, thereby actuating corresponding circuit operations.

Accordingly, the unidirectional air permeable material layer 140 mainly provides functions of waterproof and air permeable. When the user carelessly spills water on the air permeable keyboard module 100, the unidirectional air permeable material layer 140 can block water, and prevent water from flowing inside the electronic apparatus and thereby protect the electronic devices of the portable electronic apparatus. In another aspect, as the unidirectional air permeable material layer 140 has good air permeability, the heat generated by a heat source located below the air permeable keyboard module 100 may easily penetrate through the unidirectional air permeable material layer 140 and dissipated to the outside. That is, compared with the conventional PET waterproof layer, the unidirectional air permeable material layer 140 can improve the heat dissipation effect of the air permeable keyboard module 100.

In the present embodiment, the unidirectional air permeable material layer 140 is a hydrophobic fiber layer comprising, for example, a micro-pore structure. Therefore, water drops cannot pass through the micro-pore structure, and thus the unidirectional air permeable material layer 140 is provided with the waterproof property. In another aspect, air molecules can pass through the micro-pore structure to carry away the heat, such that the unidirectional air permeable material layer 140 has an air permeable property. However, the material and structure of the unidirectional air permeable material layer 140 are not limited to those described in the present invention. For example, the material of the unidirectional air permeable material layer 140 may comprise a Gore-tex fiber.

Referring to FIG. 1B again, in the present embodiment, each of the keys 130 comprises a key cap 132, a support structure 134, and an elastic protrusion 136. The key cap 132 is fixed on the bottom plate 110 via the support structure 134. The elastic protrusion 136 protrudes from the support structure 134 and contacts the bottom of the key cap 132, and the position of the elastic protrusion 136 corresponds to the touch portion 122 of the flexible PCB 120. The support structure 134 comprises a first bracket 134a and a second bracket 134b cross-pivoted, which helps to assemble the key cap 132 on the bottom plate 110, and the support structure 134 can be driven to pivot along with the change of the position of the key cap 132 (being pressed down or springing back).

When being pressed, the key cap 132 will forcefully deform the elastic protrusion 136, and get depressed such that the circuit of the touch portion 122 of the flexible PCB 120 is conducted by contact, thereby actuating the corresponding circuit operation. When the external force on the key cap 132 is released, the deformed elastic protrusion 136 generates a restoring force such that the key cap 132 springs back to the original position. However, the key 130 having the key cap 132, support structure 134, and elastic protrusion 136 is exemplified herein as an example to illustrate the embodiment of the present invention, and the constitution of the key 130 will not be limited thereto. The constitution of the key 130 is not limited to those described above.

Furthermore, in the present embodiment, the flexible PCB 120 is a thin film switch which comprises, for example, an upper conductive layer, a lower conductive layer, and an insulating plate between the upper and lower conductive layers. When the two conductive layers are pressed together (by pressing the key 130) through holes in the insulating plate, the switch is turned on. However, the type of the flexible PCB 120 is not limited in the present invention. For example, the flexible PCB 120 can also be a piezoelectric switch which mainly produces piezoelectric effect when an external force is applied to a piezoelectric chip to make the piezoelectric chip generate a practicable switching voltage or switching charge. Moreover, the flexible PCB 120 can also be a capacitance sensing switch or other suitable switch devices.

A notebook computer is exemplified below for illustrating the portable electronic apparatus of the present invention. However, the portable electronic apparatus of the present invention is not limited to a notebook computer, the present invention may also be applied to any other portable electronic devices, for example, personal digital assistant (PDA), mobile phone, and so on.

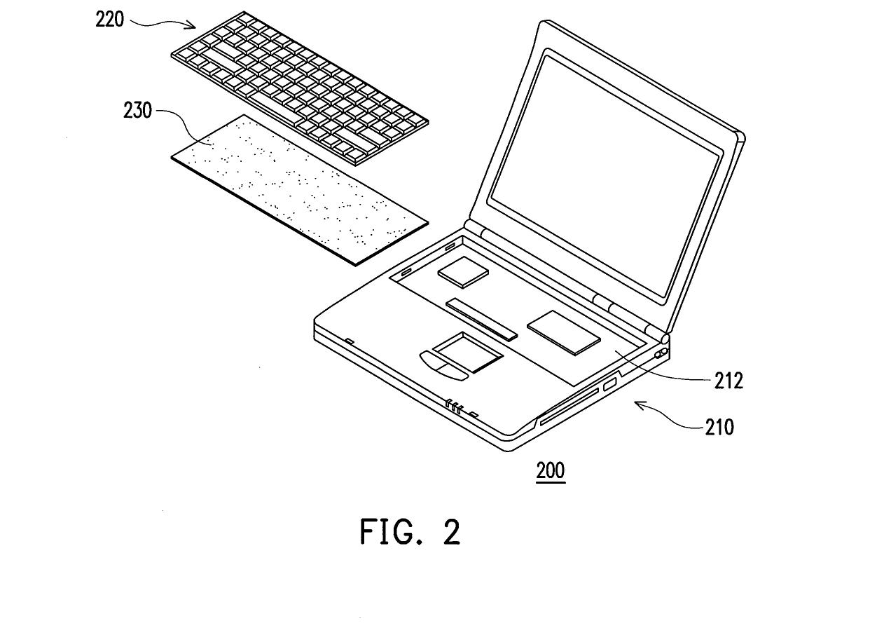

FIG. 2 is an exploded view of the portable electronic apparatus according to an embodiment of the present invention. Referring to FIG. 2, a portable electronic apparatus 200 of the present invention comprises a host 210, a keyboard 220, and a unidirectional air permeable material layer 230. The keyboard 220 may comprise the bottom plate 110, the flexible PCB 120, and the key 130 of the air permeable keyboard module 100 of the above embodiment (as shown in FIGS. 1A and 1B). The unidirectional air permeable material layer 230 can be the unidirectional air permeable material layer 140 described in the above embodiment. The host 210 has a control unit 212. The keyboard 220 is assembled on the host 210 and is electrically connected to the control unit 212. Further, the unidirectional air permeable material layer 230 is disposed between the keyboard 220 and the control unit 212.

Particularly, the unidirectional air permeable material layer 230 is disposed on the bottom surface of the keyboard 220 and mainly provides waterproof and air permeable functionalities. When the user carelessly spills water onto the keyboard 200, the unidirectional air permeable material layer 140 can block water and prevent water from flowing inside the portable electronic apparatus 200, and thereby protect the control unit 212 or other devices in the host 210. In another aspect, as the unidirectional air permeable material layer 230 is air permeable, the heat generated by the control unit 212 or other devices in the host 210 may easily penetrate the unidirectional air permeable material layer 230 and get dissipated to the outside from the keyboard 220. Therefore, the portable electronic apparatus 200 of the present invention has a better waterproof and heat dissipation effects.

In addition, as the portable electronic apparatus 200 has a better heat dissipation effect, electronic devices with better operating performance can be disposed in the portable electronic apparatus 200 to enhance the performance thereof.

In view of the above, the air permeable keyboard module and portable electronic apparatus of the present invention have at least the following advantages.

1. As the unidirectional air permeable material layer is characterized by its air permeability, the air permeable keyboard module and portable electronic apparatus have a better heat dissipation effect.

2. Electronic devices with better operating performance can be disposed in the portable electronic apparatus, thus enhancing the performance thereof.

Though the present invention has been disclosed above by the preferred embodiments, they are not intended to limit the invention. Anybody skilled in the art can make some modifications and variations without departing from the spirit and scope of the invention. Therefore, the protecting range of the invention falls in the appended claims.

What is claimed is:

1. An air permeable keyboard module, suitable for a portable electronic apparatus, comprising:
a bottom plate;
a flexible printed circuit board (PCB), disposed on an upper surface of the bottom plate and having a plurality of touch portions;
a plurality of keys assembled to the bottom plate and being disposed respectively above corresponding touch portions; and
a unidirectional air permeable material layer, disposed on a bottom surface of the bottom plate.

2. The air permeable keyboard module according to claim 1, wherein the unidirectional air permeable material layer comprises Gore-tex fiber.

3. The air permeable keyboard module according to claim 1, wherein the unidirectional air permeable material layer comprises a micro-pore structure.

4. The air permeable keyboard module according to claim 1, wherein the flexible PCB comprises a thin film switch, a piezoelectric switch or a capacitance sensing switch.

5. The air permeable keyboard module according to claim 1, wherein the portable electronic apparatus comprises a notebook computer.

6. An air permeable keyboard module, suitable for a portable electronic apparatus, comprising:
a bottom plate;
a thin film switch, disposed on an upper surface of the bottom plate and having a plurality of touch portions;
a plurality of keys, assembled to the bottom plate and disposed respectively above corresponding touch portions, wherein each of the keys comprises:
a key cap;
a support structure, for fixing the key cap on the bottom plate;
an elastic protrusion, disposed at a bottom of the key cap and corresponding to the touch portion of the thin film switch; and
a hydrophobic fiber layer disposed on a bottom surface of the bottom plate.

7. The air permeable keyboard module according to claim 6, wherein the hydrophobic fiber layer comprises a micro-pore structure.

8. The air permeable keyboard module according to claim 6, wherein the portable electronic apparatus comprises a notebook computer.

9. The air permeable keyboard module according to claim 6, wherein the support structure comprises a first bracket and a second bracket cross-pivoted.

10. A portable electronic apparatus, comprising:
a host, having a control unit;
a keyboard, assembled on the host and being electrically connected to the control unit; and
a unidirectional air permeable material layer, disposed between the keyboard and the control unit.

11. The portable electronic apparatus according to claim 10, wherein the unidirectional air permeable material layer comprises Gore-tex fiber.

12. The portable electronic apparatus according to claim 10, wherein the unidirectional air permeable material layer comprises a micro-pore structure.
